(19) United States
(12) Patent Application Publication
(10) Pub. No.: US 2003/0006803 A1
(43) Pub. Date: Jan. 9, 2003

(54) Logic or circuit

(75) Inventors: Rajiv V. Joshi, Yorktown Heights, NY (US); Ruchir Puri, New Rochelle, NY (US)

Correspondence Address: Paul J. Farrell, Esq., Dilworth & Barrese, LLP, 333 Earle Ovington Blvd., Uniondale, NY, 11553, US

(73) Assignee: International Business Machines Corporation, Armonk, NY

(21) Appl. No.: 09/900,302

(22) Filed: Jul. 6, 2001

(51) Int. Cl. H03K 19/094

(52) U.S. Cl. 326/121

(57) ABSTRACT

A MOSFET logic circuit for performing a logic OR operation is presented including three transistors, wherein at least two input signals are provided to the circuit and an output signal indicative of an OR operation performed on a first and second input signal of the at least two input signals is output from the circuit.

### FIELD OF THE INVENTION

The invention relates to the field of integrated circuit (IC) design. Specifically, it relates to a logic OR circuit. More specifically, it relates to a logic OR circuit using three MOSFET transistors.

### BACKGROUND OF THE INVENTION

High performance arithmetic operations have been widely implemented using pass-transistor based circuits known for low power usage and high performance. One type of pass-transistor based circuit employs only NMOS transistors. However, NMOS transistors suffer from signal degradation due to a threshold voltage drop across the source and drain of the transistor when passing a HIGH signal.

In a CMOS silicon-on-insulator (SOI) implementation, threshold voltage drop is minimized and performance is maximized due to the absence of a reverse body effect. Not only is the SOI implementation of an NMOS transistor body rarely reverse-biased, it tends to be forward-biased with respect to the source. Fluctuating biasing conditions and switching patterns cause a fluctuation in the forward bias of the body-to-source junction of the NMOS transistor, causing large variations in hysteretic delay.

To overcome the drawbacks associated with NMOS only pass-transistor circuits of both bulk CMOS and SOI CMOS implementations, transmission gates using both NMOS and PMOS transistors are used. VLSI circuits formed of NAND, NOR and INVERTER basic building block circuits using transmission gates are implemented using static or dynamic CMOS. Static CMOS circuits are generally more widely used due to their superior rail-to-rail voltage swing, robust behavior and high noise immunity.

However, static CMOS circuits require one NMOS and one PMOS transistor for every input signal. Furthermore, static CMOS gates are inverting by nature. This results in a large count of transistors for each basic circuit, large delays and high power consumption, as will be described with reference to FIGS. 1A and 1B.

Similarly, FIG. 1A shows a logic representation of a two input OR operation 40. The truth table for the two input OR operation 40 is shown in FIG. 2B. In static CMOS logic, the two input OR operation 40 is implemented using a two input NOR gate 42 and a second inverter gate 44. The output D of the NOR gate 42 is A NOR B. The second inverter gate outputs NOT D which is equal to A OR B. FIG. 1B shows the static CMOS logic circuit 50 for the two input OR operation 40 implementing a conventional NOR circuit 41 and a conventional inverter circuit 23. The static CMOS logic circuit 50 requires six transistors including three NMOS transistors 52, 54, 56 and three PMOS transistors 58, 60, 62. The OR operation 40 implemented in the static CMOS circuit 50 suffers from poor performance because it employs three PMOS transistors 58, 60, 62 in series. PMOS transistors are known to be inherently slower and cause a larger delay than NMOS transistors due to slower mobility of holes than electrons.

The basic logic OR circuit 50 is used as a building block in applications for various operations. The delay associated with a signal passing through multiple logic OR circuits increases proportionately to the number of logic OR circuits it passes through.

### SUMMARY

An aspect of the present invention is to provide a basic logic circuit for the OR logic operation in which the number of transistors for each circuit is reduced for minimizing the size, power consumption and associated delays of the circuit, thereby maximizing efficiency.

It is another aspect of the present invention to provide a basic logic circuit for the OR logic operation in which the number of transistors that a signal passes through in series is minimized for minimizing associated delays.

Accordingly, the present invention provides a MOSFET logic circuit having three transistors for performing a logic OR operation, wherein at least two input signals are provided to the circuit and an output signal indicative of an OR operation performed on a first and second input signal of the at least two input signals is output form the circuit.

### BRIEF DESCRIPTION OF THE FIGURES

FIG. 1A is a prior art logic representation of a logic OR function;

FIG. 11B shows a prior art circuit for implementing a logic OR function;

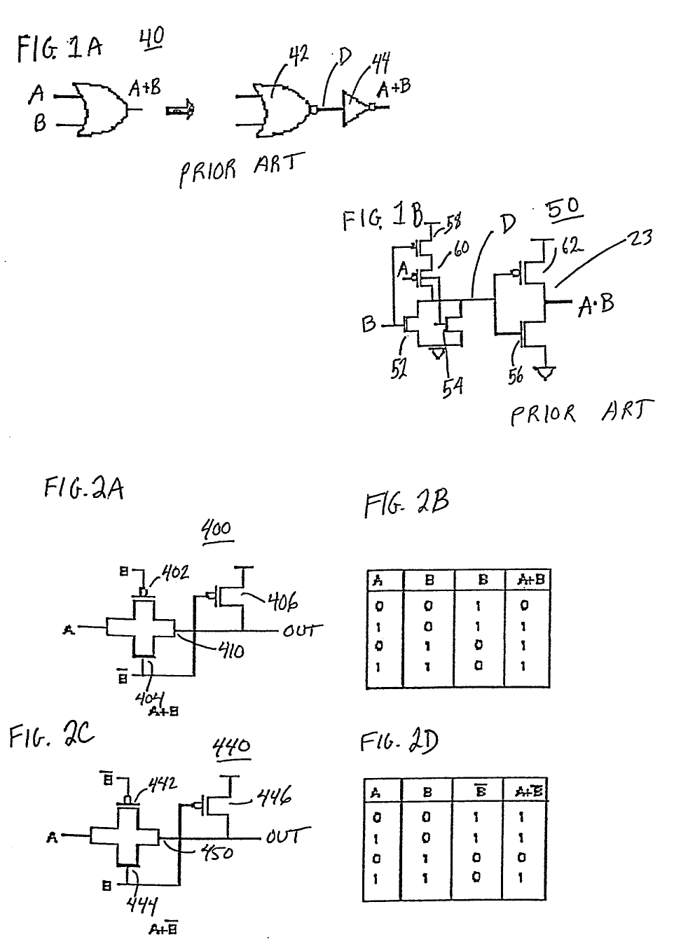

FIG. 2A shows a circuit for a logic OR function in accordance with the present invention;

FIG. 2B shows a truth table for the logic or function in accordance with the present invention;

FIG. 2C shows a circuit for a logic OR function in accordance with the present invention; and

FIG. 2D shows a truth table for the logic or function in accordance with the present invention.

### DETAILED DESCRIPTION OF THE INVENTION

The present invention provides a circuit for a logic OR operation. Three MOSFET transistors are used for the logic OR circuit. Hence, the number of components and the delay is reduced relative to the prior art.

It is to be appreciated by one skilled in the art, that reference to an input signal as being the same (or the like) as an output signal means approximately the same.

FIG. 2A shows a circuit 400 of a logic OR operation according to another embodiment of the present invention. The circuit 400, implementing the operation A OR B for input signals A, B and ˜B, includes three transistors including a PMOS transistor 402 and an NMOS transistor 404 and a pull-up PMOS transistor 406. A transmission gate 410 is formed at the junction of transistors 402, 404. Input A is provided to transistors 402, 404. Input B is provided to the gate of transistor 402 and input ˜B is provided to the gate of transistor 404. The output of the transmission gate 410 is connected to the drain of pull-up transistor 406. Input ˜B is provided to the gate of pull-up transistor 406. The output of the circuit is the OUT signal, which is equal to A+B.

Circuit 400 operates such that when input B is LOW the transmission gate 410 is closed and the output of the transmission gate 410 is the same as input A. The output of the transmission gate 410 is not pulled up by pull-up transistor 406, so the output of the circuit OUT is the same as the output of the transmission gate 410, i.e. HIGH when A is HIGH and LOW when A is LOW. The delay of circuit 400 when B is LOW is approximately equal to the delay of the transmission gate 410.

When input B is HIGH the transmission gate 410 is OPEN and the pull-up transistor 406 pulls the output of the transmission gate 410 to HIGH, so that the output of the circuit OUT is HIGH when A is HIGH and when A is LOW. The OUT signal has a voltage level approximately equal to a drain of pull-up transistor 406.The delay of the circuit when B is HIGH is approximately equal to only the delay of the PMOS pull-up transistor 406.

The truth table for the circuit 400 is shown in FIG. 2B, showing that circuit 400 implements the operation A OR B. Circuit 400 implements the OR operation with a reduced count of transistors and a reduced delay relative to the prior art.

FIG. 2C shows an implementation of a logic OR operation according to another embodiment of the present invention. Circuit 440, implementing the operation A OR ˜B for input signals A, B and ˜B, includes three transistors, including a PMOS transistor 442, an NMOS transistor 444 and a pull-up PMOS transistor 446. A transmission gate 450 is formed at the junction of transistors 442, 444. Input A is provided to transistors 442, 444. Input ˜B is provided to the gate of transistor 442 and input B is provided to the gate of transistor 444. The output of the transmission gate 450 is connected to the drain of pull-up transistor 446. Input B is provided to the gate of pull-up transistor 446. The output of the circuit is the OUT signal, which is equal to A+˜B.

Circuit 440 operates such that when input B is HIGH the transmission gate 440 is closed and the output of the transmission gate 440 is the same as input A. The output of the transmission gate 440 is not pulled up by pull-up transistor 446, so the output of the circuit OUT is the same as the output of the transmission gate 440, i.e. HIGH when A is HIGH and LOW when A is LOW. The OUT signal has a voltage level approximately equal to a drain of pull-up transistor 446. The delay of circuit 440 when B is HIGH is approximately equal to the delay of the transmission gate 440.

When input B is LOW the transmission gate 440 is OPEN and the pull-up transistor 446 pulls the output of the transmission gate 450 to HIGH, so that the output of the circuit OUT is LOW when A is HIGH and when A is LOW. The delay of the circuit when B is LOW is approximately equal to only the delay of the PMOS pull-up transistor 446.

The truth table for the circuit 440 is shown in FIG. 2D, showing that circuit 440 implements the operation A OR ˜B. Circuit 440 implements the OR operation with a reduced count of transistors and a reduced delay relative to the prior art.

What has been described herein is merely illustrative of the application of the principles of the present invention. Other arrangements and methods may be implemented by those skilled in the art without departing from the scope and spirit of the invention.

1. A MOSFET logic circuit for performing a logic OR operation comprising three transistors, wherein at least two input signals are provided to the circuit and an output signal indicative of an OR operation performed on a first and second input signal of the at least two input signals is output from the circuit.

2. The logic circuit as in claim 1, wherein the three transistors include first and second PMOS transistors and one NMOS transistor.

3. The logic circuit as in claim 1, wherein first and second transistors of the three transistors form a transmission gate outputting one signal.

4. The logic circuit as in claim 1, wherein the first input signal is provided to a source of first and second transistors of the three transistors, the second input signal is provided to a gate of the second transistor, and a complement of the second input signal is provided to a gate of the second transistor.

5. The logic circuit as in claim 3, wherein a complement of the second input is provided to a gate of a third transistor of the three transistors.

6. The logic circuit as in claim 1, wherein the at least two input signals to the circuit further comprise a complement of the second input signal.

7. The logic circuit as in claim 3, wherein when the second input signal has a logic LOW level the output of the logic circuit is an output signal of the transmission gate.

8. The logic circuit as in claim 3, wherein a third transistor of the three transistors is a pull-up transistor, and when the second input signal has a logic HIGH level the output of the logic circuit has a voltage level approximately equal to a drain of the third transistor, which pulls up the output signal from the transmission gate to a logic HIGH level.

9. The logic circuit as in claim 1, wherein a delay of the logic circuit is one of a delay of a transmission gate formed by first and second transistors of the three transistors, and a delay of a third transistor of the three transistors.
